(19) United States
(12) Patent Application Publication
(10) Pub. No.: US 2010/0320497 A1
(43) Pub. Date: Dec. 23, 2010

(54) LED bracket structure

(76) Inventor: Han-Ming Lee, Hsin Chu City (TW)

Correspondence Address: Lee, Han-Ming, P.O. BOX 7-820, TAIPEI, TW

(21) Appl. No.: 12/456,478

(22) Filed: Jun. 18, 2009

(51) Int. Cl. H01L 33/00

(52) U.S. Cl. 257/99; 257/E33.066

(57) ABSTRACT

The present invention relates to a new LED bracket structure and in particular to a bracket that adopts the structure in which the upper section and lower section are made of different materials, the main improvements including: the bottom of the bracket is provided with a groove for embedding and fixing of a conductive pin, the bracket may be made of other conductive materials such as iron plated with silver, and the conductive pin may be made of red brass and bronze of good conductive performance so as to reduce the consumption of copper in this structure and the consumption of precious metal copper significantly.

### BACKGROUND OF THE INVENTION

The structure of traditional LED lamp is shown in FIG. 8. Chips are provided in the chip cup installed above the integrated copper bracket to connect to power supply at the bottom to give off light. In consideration of the surge in demand for precious metal copper around the world and limited copper mine resources, this structure undoubtedly increases the cost of the manufacturers and reduces their competivity, so the improved structure of this LED lamp indeed contributes to environment protection and energy saving.

### SUMMARY OF THE INVENTION

The primary purpose of the present invention is to provide a new LED bracket structure and in particular to one that is provided with a groove at the bottom for embedding and fixing of a conductive pin so that the upper section and lower section may be made of different materials to reduce the consumption of precious metal copper significantly.

The secondary purpose of this invention is to provide a new LED bracket structure, wherein the bracket may be made of other conductive materials such as iron plated with silver, and the conductive pin may be made of red brass and bronze of good conductive performance so as to reduce the consumption of copper in this structure significantly.

Another purpose of this invention is to provide a new LED bracket structure, wherein the structure of the bottom of the bracket connected to conductive pin may also be connected by means of copper pipe riveting, electrode welding, welding, binding and riveting so that the upper section and the lower section are made of different materials.

### BRIEF DESCRIPTION OF THE DRAWINGS

FIG. 1 is a 3D diagram of the present invention.

FIG. 2 is a schematic diagram of the components of the present invention.

FIG. 3 is a cross-section 3D diagram of the present invention.

FIG. 4 is a schematic of composition of the bracket of this invention.

FIG. 5 is a schematic of the conductive pin of this invention embedded into the bottom of the bracket.

FIG. 6 is a schematic of another embodiment of the conductive pin of the present invention.

FIG. 7 is a schematic of another embodiment of the conductive pin of the present invention.

FIG. 8 is a schematic of the traditional structure.

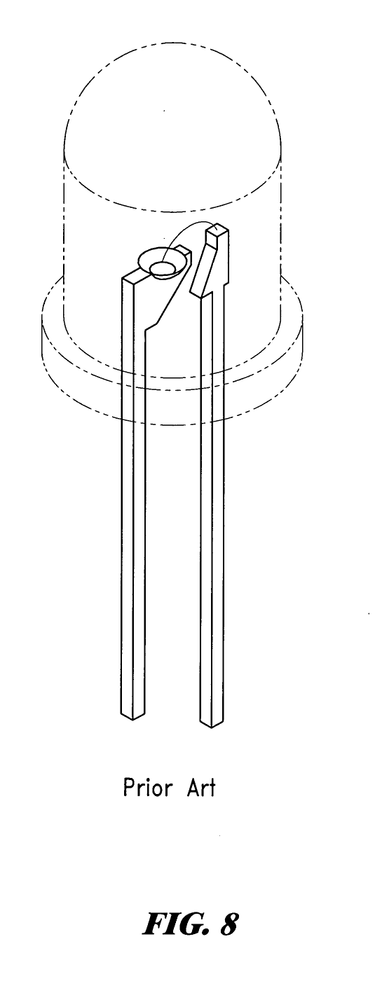

### DETAILED DESCRIPTION OF THE PREFERRED EMBODIMENT

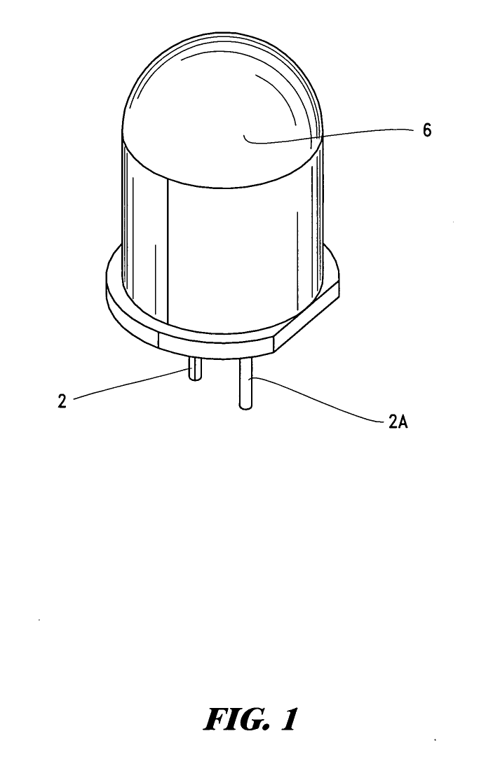

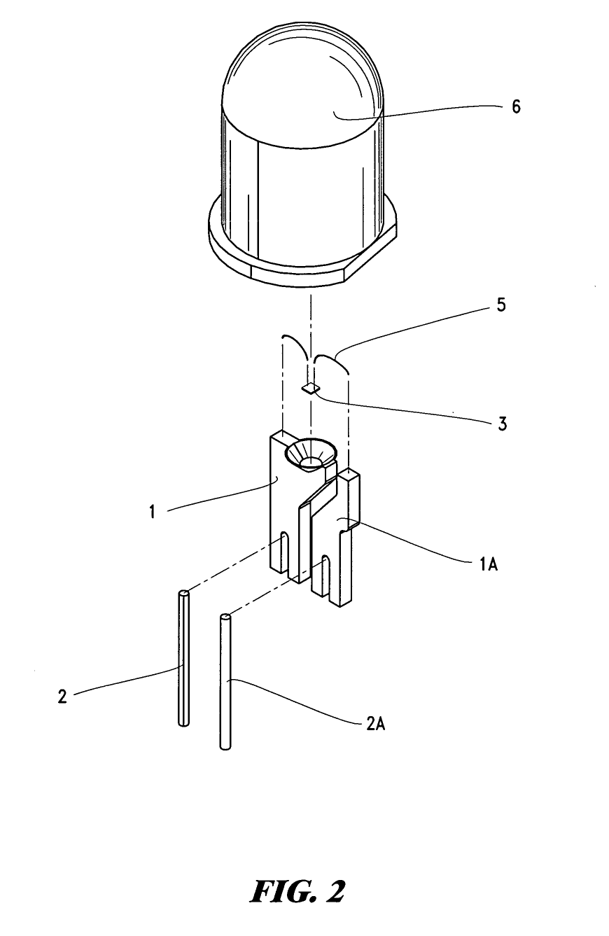

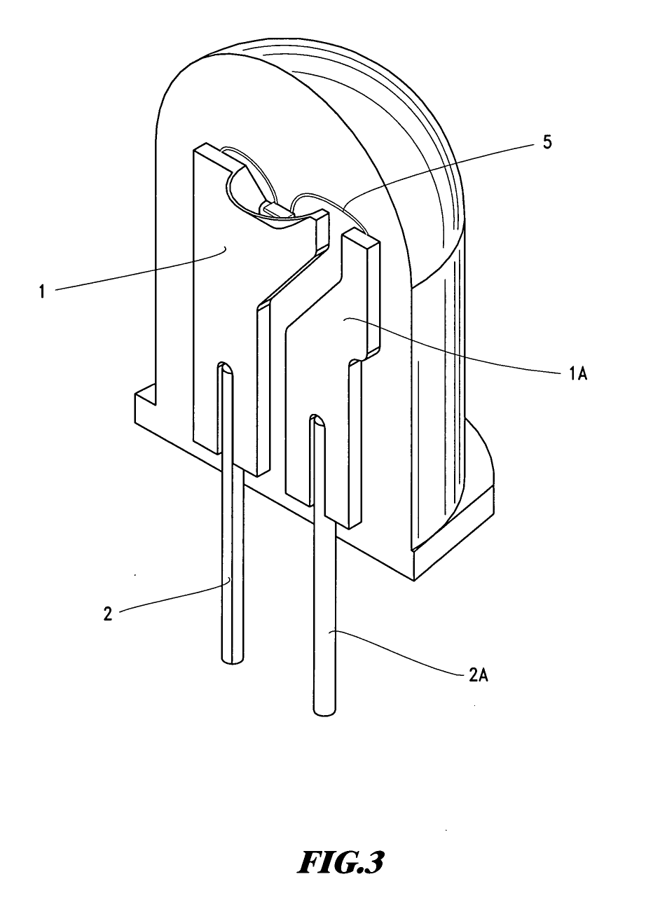

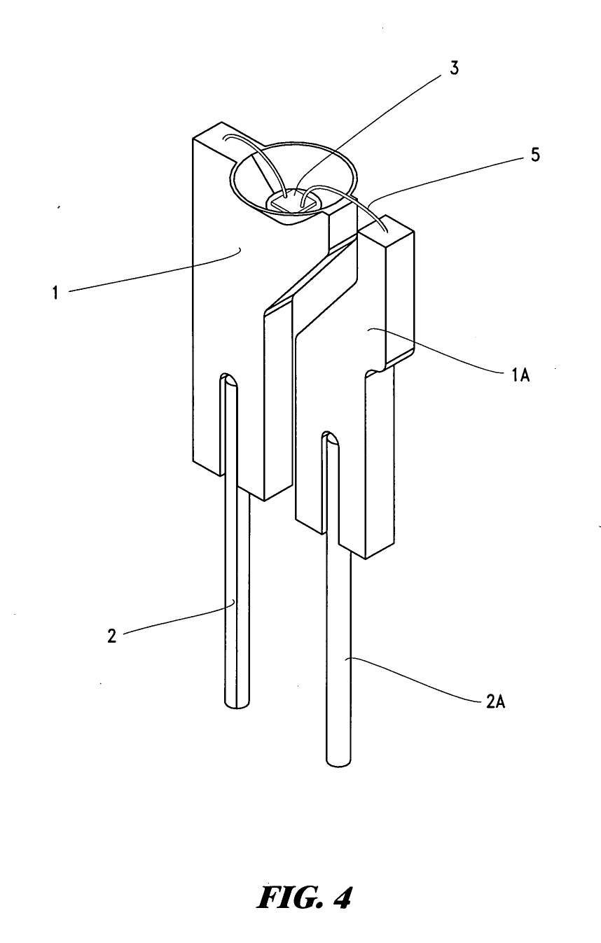

Please refer to FIGS. 1 through FIGS. 4. This invention relates to a new LED bracket structure, comprising brackets 1 and 1A, conductive pins 2 and 2A, chip 3, conductive wire 5 and silicon lamp housing 6; the main improvements including: the bracket 1 is a traditional bracket structure with chip cup provided at the top, the bottom of the bracket is provided with a groove 12; the bracket 1A is provided outside the bracket 1, the bottom of bracket 1A is also provided with a groove 12A; the conductive pins 2 and 2A are made of red brass and bronze of good conductive performance for fixing of grooves 12 and 12A at the bottom of brackets 1 and 1A; the chip 3 is a lighting semi-conductor chip fixed inside the chip cup; the conductive wire 5 is made of conductive material connecting chip 3 and bracket 1A; the silicon lamp housing 6 is made of resin or silicon transmitting material and integrated with the brackets 1 and 1A, conductive pins 2 and 2A, chip 3 and conductive wire 5.

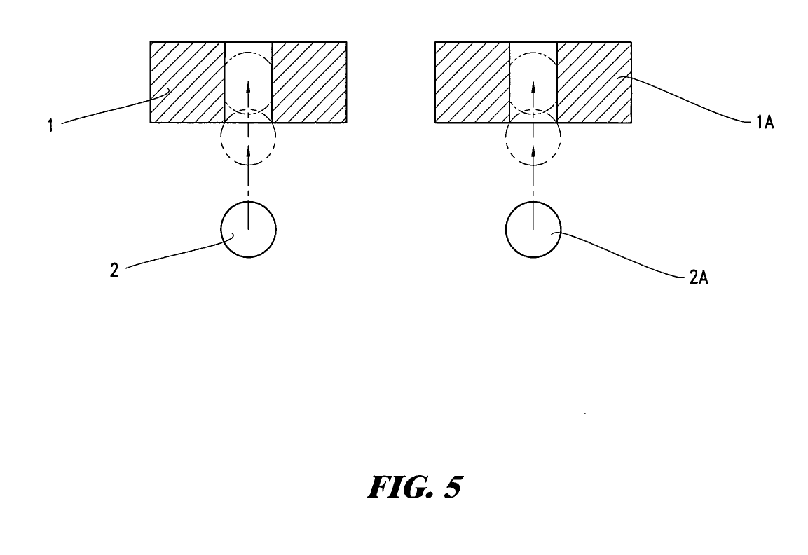

Please refer to FIG. 5 for another embodiment of this invention. The bottom of the brackets 1 and 1A are provided with the grooves 12 and 12A for embedding and fixing of the conductive pins 2 and 2A. The brackets 1 and 1A are made of other materials such as iron plated with silver while the conductive pins 2 and 2A are made of red brass and bronze of good conductive performance so as to reduce the consumption of precious metal copper for the traditional bracket structure and the consumption of precious metal significantly.

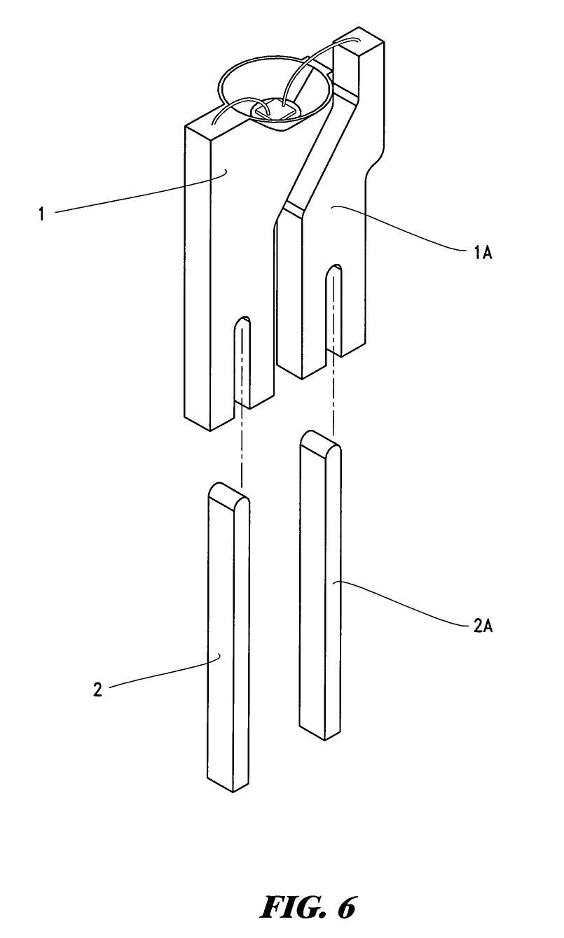

Please refer to FIG. 6 for one more embodiment of this invention. The conductive pins 2 and 2A of this invention are of shape design slightly greater than the grooves 12 and 12A for doubling the embedding and fixing functions.

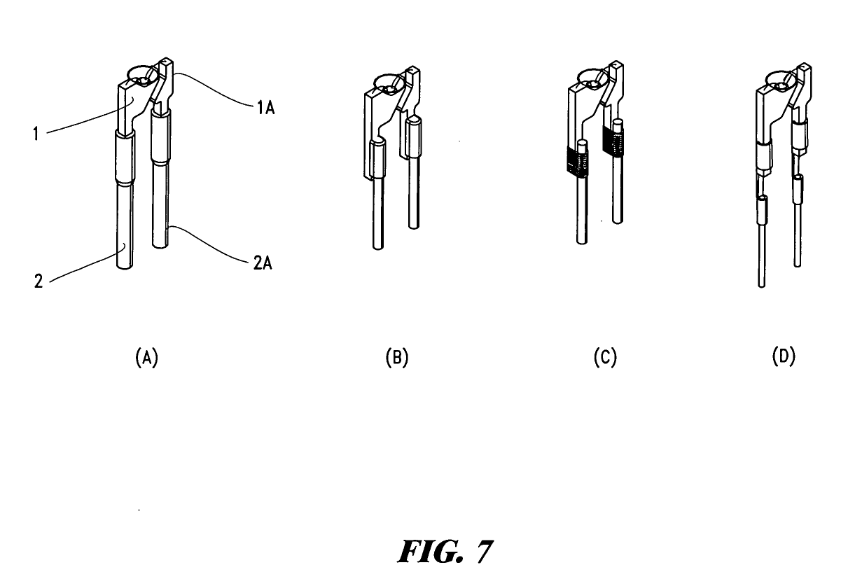

Please refer to FIG. 7 for one more embodiment of this invention. The bottom of the brackets 1 and 1A are provided with structure design for connecting the conductive pins 2 and 2A, which can be connected by means of cooper pipe riveting (A), electrode welding or welding (B), binding (C) and riveting (D) as shown in the figure so that the upper section and lower section made of different materials are combined.

I claim:

1. A new LED bracket structure, comprising two brackets, two conductive pins, chips, conductive wires and silicon lamp housing, the main improvements including: the bottom of the two brackets is provided with a groove for embedding and fixing of two conductive pins, wherein the bracket may be made of other conductive materials such as iron plated with silver and the conductive pins are made of red brass and bronze of good conduction performance to significant reduce the consumption of precious metal copper for the traditional bracket.

2. The new LED bracket structure according to claim 1, wherein the structure in which the bottom of the bracket is combined with conductive pins may also be connected by means of welding, binding and riveting.
